(19) United States
(12) Patent Application Publication
(10) Pub. No.: US 2003/0225713 A1
(43) Pub. Date: Dec. 4, 2003

(54) Prepayment system for power distribution using RFID technology

(76) Inventors: Roger F. Atkinson, El Cajon, CA (US); Alan Jack Herr, San Diego, CA (US)

Correspondence Address: EDELL, SHAPIRO & FINNAN, LLC, Suite 400, 1901 Research Boulevard, Rockville, MD, 20850-3164, US

(21) Appl. No.: 10/377,096

(22) Filed: Mar. 7, 2003

Related U.S. Application Data
(60) Provisional application No. 60/362,385, filed on Mar. 8, 2002.

(51) Int. Cl. G01R 11/56; G06F 17/00; G01R 21/133

(52) U.S. Cl. 705/412

(57) ABSTRACT

A prepayment system for electric power or other utility commodity distribution uses radio frequency identification (RFID) tag technology to store and transfer value (money or KWh) from the retail vendor to the customer, and deliver power to the customer from the power distribution system. The customer purchases power at a retail outlet in the form of a credit to his Card containing an RFID tag. The Card is credited for the amount purchased by the store clerk, using the store's Sales Terminal. The customer takes this Card to his residence or small business and holds it up to the RFID reader/writer sealed into the face of the System Controller. This System Controller is installed at a convenient location near, on or within his premises. Alternatively, he may use an optional Remote Terminal installed inside his premises. In either case, the display associated with the reader/writer indicates to the customer the amount of power remaining. The System Controller then stores the new deposit in the Meter/Contactor associated with the particular customer's circuit. Mounted at the top of the pole, on the building or inside the building, the Meter/Contactor measures usage, decrements the customer's credit, and shuts off power if the credit is depleted.

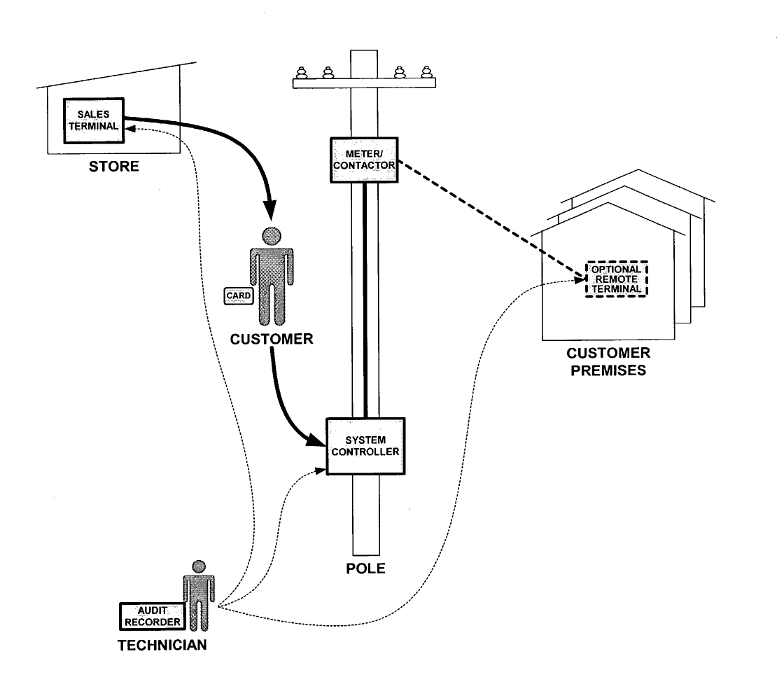

### CROSS-REFERENCE TO RELATED APPLICATIONS

This application relies for priority on provisional application serial No. 60/362,385 filed Mar. 8, 2002 and entitled “Prepayment System For Power Distribution Using RFID Technology”.

### System Description

1. System Overview

1.1. This prepayment system for power distribution uses radio frequency identification (RFID) tag technology to store and transfer value (money or KWh) from the retail vendor to the customer, and deliver power to the customer from the power distribution system. RFID tags provide a secure read/write medium in a credit card format, without the maintenance woes of magnetic stripes or electrical contacts. This technology is particularly valuable in dusty or damp environments where conventional card readers experience high failure rates. These environmentally sealed cards and reader/writers also provide for high security, detailed audit trail, secure craft access and virtually endless flexibility and expansion possibilities.

1.2. The system, composed of the components shown in the graphic below, operates as follows: The customer purchases power at a retail outlet in the form of a credit to his Card containing an RFID tag. The Card is credited for the amount purchased by the store clerk, using the store's Sales Terminal. The customer takes this Card to his residence or small business and holds it up to the RFID reader/writer sealed into the face of the System Controller. This System Controller is installed at a convenient location near, on or within his premises. Alternatively, he may use an optional Remote Terminal installed inside his premises. In either case, the display associated with the reader/writer indicates to the customer the amount of power remaining. The System Controller then stores the new deposit in the Meter/Contactor associated with the particular customer's circuit. Mounted at the top of the pole, on the building or inside the building, the Meter/Contactor measures usage, decrements the customer's credit, and shuts off power if the credit is depleted.

1.3. A power company technician or auditor uses his Audit Recorder to read the status and transaction history of all components of the system, update time and rate tables and set date/time. The Audit Recorder is also used to allow the technician to turn power on and off so that he can maintain the system safely.

1.4. RFID tags are permanently programmed with the customer's meter number. A Sales Terminal credits power purchases, and a System Controller or Remote Terminal on or near the customer premise debits power usage. All transaction details are stored on the Card, along with extensive audit trail data.

1.5 The configurations described here are examples of how the system may be used in the field. Please see 2.3.5 below for some alternative configurations, including a single customer version in which the System Controller functions are packaged into the Meter/Contactor housing.

2. Major System Components

2.1. Sales Terminal

2.1.1. The Sales Terminal is comprised of the following:

2.1.1.1. RFID tag reader/writer built into the top or front surface of the Sales Terminal.

2.1.1.2. Display showing at least the following:

2.1.1.2.1. Meter number

2.1.1.2.2. Rate category, i.e. residential, commercial, industrial, etc. There may be multiple rates within each of these categories and scale factors may be applied to each rate. A general purpose LCD (e.g. ¼ VGA) allows the most flexibility.

2.1.1.2.3. Credit balance in KWh or monetary value stored in the RFID tag

2.1.1.2.3.1. A credit balance will occur when a customer wants to purchase additional power before transferring the existing balance into the meter. There may also be a balance remaining because the meter was full and would not accept all of the available credit during the previous transfer.

2.1.1.2.3.2. The credit balance capability also provides a means of transferring credit back to the Sales Terminal when a customer terminates service with energy credit left unused on the meter.

2.1.1.2.4. Amount of the purchase in KWh or monetary value

2.1.1.3. Keyboard for entering amount purchased and occasionally the meter number if a new RFID tag is being issued.

2.1.1.4. Printer

2.1.1.4.1. Prints customer receipts.

2.1.1.4.2. Also used to print out audit reports (usually daily) so that the auditor/clerk/proprietor would be able to reconcile the sales terminal with the cash drawer prior to leaving the business establishment.

2.1.1.5. A low power microprocessor with a large flash memory or hard disk for reading and writing tags, running the display and storing a complete audit trail of all transactions.

2.1.1.6. The Sales Terminal is enclosed in a small sealed desktop box. The keyboard, display and RFID tag reader/writer are sealed against liquids and dust. The printer is located within a separate compartment, sealed off from the rest of the enclosure, or in its own box external to the Sales Terminal enclosure.

2.1.1.7. Alternative configuration: Instead of an integrated processor, display, keyboard, printer and RFID reader/writer, the sales terminal may consist of a stock personal computer (PC) with an external printer and an RFID reader/writer unit plugged into the PC.

2.1.2. Sales Terminal Operation

2.1.2.1. Sales Terminal Typical Transaction

In normal operation, the sales clerk scans his or her own RFID tag over the reader, optionally enters a PIN, and then places the customer's tag on the reader. The balance in the tag (usually zero) is displayed. The clerk then enters the number of KWh or the monetary value purchased. When the clerk is sure the number is correct, he or she ends the transaction by pressing a button on the keyboard. This value is added to the balance stored in the tag, and the new balance is then written into the tag, along with audit trail information. The information just written into the tag is read back for confirmation. The printer then prints a receipt.

The Sales Terminal automatically reads and display RFID tag information such as balance, but the clerk must press the appropriate key(s) before anything is written into a customer's tag.

2.1.2.2. Sales Terminal Security

The Sales Terminal should not be allowed to write credits into a customer's RFID tag without first reading and recording the sales clerk's ID from his/her RFID tag. Optionally, the clerk may also be required to enter a PIN. These steps are equivalent to keeping the cash drawer locked when the register is unattended. It also facilitates tracking fraudulent transactions.

Careful attention must be paid to security, including collection of a thorough audit trail. Even if all audit precautions are not immediately implemented, the system will be designed to collect and store the raw data on all aspects of each transaction for a period of at least one year, preferably three years. The data will be stored in predefined variable length fields for retrieval and import into accounting or database programs. This is necessary to allow future tightening of security or investigation of suspected fraud. These simple audit trail storage functions must be designed into the system from the beginning, since it is extremely difficult to add them after the system is in the field. See 5.2 below.

2.2. RFID Tag Technology

2.2.1. RFID tags are a rugged non-contact read only or read/write medium for storing and transporting information securely. Particularly applicable to distributed systems in which a robust centralized data network is not practical, these environmentally sealed devices reliably store up to 16 KB of user data and deliver it anywhere. The tags can easily be embedded in a credit card or hung on a key chain. For more information, please see http://www.aimqlobal.orq/technologies/rfid/.

2.2.2. RFID tag technology is an established solution to the problems of dirt and other contamination of magnetic stripe and embedded chip smart cards and their readers. In addition to their increased reliability and virtually non-existent maintenance costs, the purchase cost of RFID reader/writers is lower than that of magnetic stripe card reader/writers, which must capture the card and move it with a motor in order to write. While the cost of the magnetic stripe cards themselves is low, this savings is offset by the acquisition and maintenance costs of the reader/writers. Furthermore, magnetic stripe cards are themselves notoriously unreliable due to scuffing and abrasion of the stripe as well as susceptibility to stray magnetic fields. The costs of embedded chip smart cards and their reader/writers is comparable to that of RFID tags and their reader/writers, without the maintenance free advantage of RFID technology.

| | Magnetic | Embedded | RFID |
|---|---|---|---|
| | Stripe | Chip | Tag |
| Reader/Writer | VERY LOW | LOW | VERY HIGH |
| Reliability | | | |
| Card Reliability | VERY LOW | LOW | VERY HIGH |
| Reader/Writer | VERY HIGH | VERY LOW | LOW |
| Purchase Cost | | | |
| Card Purchase Cost | VERY LOW | LOW | LOW |

2.2.3. The availability of sealed reader/writers and inexpensive rugged media (less than a dollar) makes possible a simple system installation. A single System Controller can be installed indoors or outdoors, and can serve numerous customers without the equipment and skilled labor expense of installation and maintenance of terminals inside each customer premise.

2.2.4. RFID Tag Alternatives

2.2.4.1. The most common

2.2.4.2. RFID tags are about the diameter and thickness of a quarter; this format can be easily packaged into a credit card format. Alternatively, RFID tags can be packaged a variety of other ways and still perform the same function.

2.2.4.3. Although RFID tags are most appropriate for this application, the system may also be implemented with magnetic stripe cards, smart cards with embedded memory or with any other portable read/write storage technology.

2.2.5. Generic RFID tags enable customers to turn the power on in emergencies and after hours, when a store with a Sales Terminal is unavailable. Generic tags, preprogrammed with small energy amounts, could be obtained from vending machines or other sources. These generic tags could be accepted by any individual (single customer) System Controller or Remote Terminal. If the customer were only served by a multiple meter System Controller, he could first scan his personal (non-generic) depleted tag to identify his particular meter, then scan the generic tag to credit that selected meter, thus turning the power on.

2.3. System Controller

2.3.1. The System Controller is comprised of a system processor and a reader/writer/display. The System Controller serves as the user interface to the system and controls the operation of one or more Meter/Contactors with which it is associated.

2.3.2. System Controller Operation—Account Balance Display

The processor in the System Controller reads the meter number and credit balance from the customer's RFID tag using the reader/writer/display. It also reads additional data from the RFID tag and stores a record of the entire transaction in a non-volatile audit file in the system processor. The system processor then sends an encrypted message to the appropriate Meter/Contactor (the customer's meter number stored in the RFID tag determines which one if there are multiple Meter/Contactors). The message requests the customer's account balance, which is contained in a non-volatile software register within the Meter/Contactor. The system processor causes the display on the face of the System Controller to show this amount.

The System Controller displays the balance in the customer's account register anytime an RFID tag is read. If the credit balance stored in the tag is zero, the balance in the account balance register of the Meter/Contactor associated with that tag will still be displayed, but no credit transaction will take place. This is how the customer can determine the balance in his/her account (remaining KWh or money). There are several ways to indicate this remaining balance, and several possible display arrangements.

2.3.3. System Controller Operation—Credit to Account

If the credit balance in the RFID tag is greater than zero and the customer continues to hold the tag up to the system controller for several seconds, the system processor prepares to credit the customer's balance in the Meter/Contactor by the amount of the credit balance in the RFID tag. (If the amount to be credited would overflow the account balance register, only a portion of the credit balance in the RFID tag will be used.) The system processor writes the amount to be debited and the date and time into the tag. (This audit trail information will be read and logged by any Sales Terminal the next time power is purchased.) It then writes the new balance (usually zero) in place of the credit balance stored in the tag and reads the tag again to confirm that the credit balance is now correct. This process takes well under a second. The tag can be in motion during this process as long as it remains within range of the reader.

Only after confirming that the transaction with the RFID tag is complete does the system processor send another encrypted message to the appropriate Meter/Contactor, directing it to increment the customer's account by the amount of the credit balance debited from the RFID tag. Should an impending power failure be detected during this series of transactions, the system processor and Meter/Contactor will complete the transaction before shutting down.

2.3.4. System Controller Operation—Debiting Account to Zero

Should the customer wish to terminate his service and recover his remaining account balance, he merely holds his RFID tag up to the System Controller for some predetermined long period (tens of seconds). If this holding time is exceeded, the system processor warns the customer that power is about to be shut off. If the RFID tag remains present for an additional pre-determined period (several seconds), the system processor credits the RFID tag with the customer's account balance and sends a message to the Meter/Contactor requesting that it decrement that balance to zero, thus shutting off the power. These timeout periods are intentionally long so that customers are unlikely to shut off power accidentally. The customer may now take this card to a sales outlet, and either receive a refund, receive a credit on another card coded for the meter at the new location or possibly have the account number on the card changed to match the meter number at his new location. A company employee using an Audit Recorder could also perform this task. The system is flexible; operating details can vary to suit business and cultural considerations.

2.3.5. System Controller Packaging & Applications:

2.3.5.1. Shared System Controller

The System Controller is normally housed in a sealed and hardened enclosure, with the reader/writer/display visible behind a thick tempered glass or polycarbonate face. This arrangement allows the user to scan his RFID tag and read the display, while protecting the unit from weather, tampering and vandalism. Several Meter/Contactors are connected to this single System Controller. The low voltage wiring from the System Controller to the Meter/Contactors is normally protected from vandalism by conduit.

This common System Controller arrangement is cost effective in multiple customer configurations because the System Controller components are shared by all customers served by the same transformer. It may be mounted anywhere that allows easy customer access, indoors or outdoors, sheltered or exposed. Common mounting options: In or near a shared utility or meter room, in a foyer or service entrance of a shared building, on a pole below the transformer serving a cluster of dwellings, in front of a small group of houses or apartments. (The latter is where conventional meters are frequently located in newer neighborhoods in and around Puerto Vallarta, Mexico, for instance.) Retrofits are simple: Replace existing meters with Meter/Contactors, and wire them all to a common System Controller.

2.3.5.2. Dedicated System Controller Integrated Into Meter/Contactor

The System Controller functions, including reader/writer/display and system processor, may be integrated into the Meter/Contactor unit for single customer installations. With this configuration, the reader/writer/display is embedded in the face of the Meter/Contactor. The customer holds his card up to the face of the Meter/Contactor; he also reads his credit balance there. One option for packaging is to enclose the unit in the familiar tempered glass bowl used to house conventional ANSI Form 2S meters used in North America.

This is the lowest cost non-shared configuration; it is appropriate for meter locations readily accessible to the customer.

2.4. Remote Terminal

2.4.1. The Remote Terminal consists of a reader/writer/display and a simple processor in an attractive indoor enclosure. It is packaged for installation within an individual customer's premises or in a secure shared location such as the lobby of an office or apartment building. The Remote Terminal is connected by low voltage wiring to its System Controller, either directly or through a Meter/Contactor. Communications are encrypted for security. This unit can have an alarm that alerts the customer when a preset remaining power level is reached. Example: When the balance is down to 1000 watt hours remaining, a flashing LED and/or re-settable audible alarm would notify the user that he is low on energy.

2.4.2. Remote Terminal Applications

One or more Remote Terminals may function as remote reader/writer/displays for individual Meter/Contactors controlled by a common System Controller. (There is only one System Controller for one or more Meter/Contactors.) This allows customers in a shared system to access a reader/writer/display at a more convenient location, including a location within their private premises.

The system processor can be programmed to accept any valid RFID tag. (A meter number is valid if it corresponds to a Meter/Contactor connected to that system processor.) The system processor then sends the credit to that meter regardless of whether the System Controller or a Remote Terminal actually reads the tag. Alternatively, the system processor can be programmed to ignore an RFID tag whose meter number does not match the meter associated with the Remote Terminal that reads the tag. It is also possible to code the RFID tag with a generic meter number that credits the account associated with whichever Remote Terminal reads it. (See 2.2.5 above.) These operational choices are dependent on cultural and business considerations, and are mentioned here to show some of the many possibilities available.

2.5. Meter/Contactor

2.5.1. The Meter/Contactor measures usage in Watt hours and disconnects power when usage exceeds the amount for which the customer has pre-paid. The Meter/Contactor is connected between the power distribution network and the customer premises. Major components include a Watt hour meter, meter processor, and a contactor.

2.5.1.1. Watt Hour Meter

Using conventional circuitry, the Watt hour meter accurately measures power with sufficient accuracy to satisfy applicable regulatory bodies over the normal range of temperature, power factor and radiated or conducted EMI. By default, it records reverse current flow as if it were forward current, thus defeating fraudulent reverse connections. For co-generation applications, the circuit may be optioned to record reverse current flow as a credit to the customer account.

2.5.1.2. Meter Processor

The meter processor credits a non-volatile register with the amount of customer payments in money or Watt hours. It decrements (debits) this customer account register (in real time) in response to usage signals from the Watt hour meter circuit. If the value in a customer account register is decremented to zero, the contactor is disabled, thus turning off power to that customer premise. The power will remain off until the associated account register is credited as a result of reading a credit balance from the customer's RFID tag.

2.5.1.3. Contactor

The contactor connects and disconnects the customer drop under control of the meter processor. It is mechanically bi-stable, so that no power is required to maintain the contactor in either state. For three wire single phase circuits, the contactor may be either a single two pole device, or a pair of single pole units operated simultaneously.

2.5.1.4. Optional Over Current Protection

If the Watt hour meter circuit senses a prolonged over current condition, the meter processor may optionally be set to respond by disconnecting the load after a set delay. This function may be used to choke off excessive customer demand to protect the distribution network.

2.6. Audit Recorder

2.6.1. The Audit Recorder is a hand held, battery powered maintenance and administration tool used by power company personnel. It can read and write RFID tags, and has the unique ability to behave like an RFID tag when held near an RFID reader/writer. This latter feature gives it the ability, using the same electromagnetic coupling technique that is used to communicate with RFID tags, to communicate with Sales Terminals, System controllers, and Remote Terminals in order to perform a variety of tasks not available to unauthorized users.

In addition to its RFID reader/writer/communicator described above, the Audit Recorder incorporates a keyboard, display, audit processor and a very large non-volatile storage capacity.

2.6.2. The Audit Recorder can be programmed to serve a variety of purposes depending upon the authority granted to the user. Units may be permanently restricted to certain uses, or may be capable of any preprogrammed function depending upon the permissions encoded into the user's RFID tag, as further confirmed by the entry of a PIN on the keyboard.

2.6.3. In operation, an employee approaches a Sales terminal, System Controller or Remote Terminal, enters a desired function on the Audit Recorder keyboard, and then holds the Audit Recorder up to the reader/writer as if the Audit Recorder were, itself, an RFID tag. The Audit Recorder communicates the desired action or request to the Terminal or Controller, receives a response, displays appropriate messages on the Audit Recorder 's display, and records the transaction in the non-volatile, tamper-resistant audit file.

3. Electrical Interconnections

3.1. System Controller (or Remote Terminal) Connections to Meter/Contactor

3.1.1. Two unshielded twisted pairs, 24 AWG

3.1.1.1. Control pair

3.1.1.1.1. EIA-485 asynchronous serial

3.1.1.1.2. Half duplex

3.1.1.1.3. Bit rate TBD

3.1.1.2. Power pair

3.1.1.2.1.24 VDC

3.1.1.2.2. Maximum current TBD

3.2. Power Line Carrier (PLC) Connections to Meter/Contactor

3.2.1. An optional private Remote Terminal may be powered from an AC outlet on the customer's premises. PLC technology provides reliable low speed digital communications to such units, at a cost that is frequently far less than running separate cables to each such unit.

The disadvantage of the PLC approach is that there is no power available to operate the Reader/Writer when the account has been depleted. A shared System Controller (on the pole or in some other common area) must be available to users needing to restore power after their account had been depleted.

3.2.2. It may be desirable to provide a display only unit within some customer premises while still enjoying the cost advantage of the shared System Controller. If a shared System Controller or Remote Terminal is provided in a public area, a simple remote display may be plugged into any AC power outlet in the customer's premises. Communications is via power line carrier technology (PLC). Since there is no reader/writer in this unit, loss of power is not an issue.

4. Data Stored in RFID Tag

4.1. Read From RFID Tag By Sales Terminal

4.1.1. Meter number

4.1.1.1. This number is recorded when the RFID tag is issued, and should normally not be changed thereafter (see 2.3.4 above for a possible exception).

4.1.1.2. The last two digits of the meter number identify the particular user on the transformer. This allows more than 10 customers and associated meters on a single transformer. (100 users is more than enough, but 10 may be insufficient.)

4.1.1.3. Meter number is displayed on the Sales Terminal.

4.1.1.4. If meter number is all zeros, the tag is new (blank). A new tag must have a meter number written before it can be used. The clerk can initialize a new tag by consulting a data base to obtain the customer's meter number and then entering this number into the Sales Terminal. The clerk may only have to do this when issuing a replacement tag, since the power company will generally issue new tags (TBD).

4.1.2. Credit balance (in KWh or money) remaining on the tag, if any. This balance is also displayed on the Sales Terminal. The value will usually be zero.

4.1.3. Details of last sales and debit transactions (collected for audit log but not displayed).

4.1.3.1. Sales Terminal serial number

4.1.3.2. Selling clerk's ID number as read from clerk's personal RFID tag at time of sale

4.1.3.3. KWh or monetary value sold in previous sale

4.1.3.4. Date and time of previous sale

4.1.3.5. KWh or money debited in previous debit transaction

4.1.3.6. Date and time of previous debit transaction

4.1.4. The above data is recorded in the Sales Terminal's audit log, along with the current date/time stamp, as part of each read transaction. (Please see 5 below.)

4.1.5. A transaction may involve a read without a write. It is still logged.

4.2. Written To RFID Tag By Sales Terminal

4.2.1. Sales Terminal serial number (cannot be changed in the field)

4.2.2. Selling clerk's ID number

4.2.2.1. Read from his/her RFID tag

4.2.2.2. The clerk's ID number cannot be changed in the field.

4.2.3. KWh or monetary value sold in current sale

4.2.4. Date and time of current sale

4.2.5. New credit balance on tag, including pre-existing credit balance, if any. A credit balance could occur if more power is purchased before the tag is debited, or if a balance is transferred from the meter to the card when the customer terminates service.

4.2.6. The above data is also recorded in the Sales Terminal's audit log as part of each sales transaction.

4.3. Read By System Controller From RFID Tag

4.3.1. All RFID tag entries written above

4.4. Written By System Controller To RFID Tag

4.4.1. KWh or monetary value debited in current transaction

4.4.2. Date and time of current debit transaction

4.4.3. New balance on tag, usually zero. This feature allows for partial debits. One example of such is when the credit balance on the card would, when added to the credit balance in the account register, cause the account register in the Meter/Contactor to overflow.

4.4.4. The above data is recorded in the system processor's audit log, along with the current date/time stamp, as part of each debit transaction.

5. Collection Of Audit Data

5.1. Audit data is stored as an integral part of all transactions, in both Sales Terminals and in System Controllers. It is the responsibility of the system operator (power company) to collect and analyze this data in order to detect and prevent fraud. A battery powered handheld Audit Recorder is provided for this purpose. The Audit Recorder interfaces to the Sales Terminal and to the System Controller or Remote Terminal using the same electromagnetic coupling mechanism used to read and write RFID tags. A direct connection is not required.

The Audit Recorder contains sufficient data storage capacity to audit a dozen or more Sales Terminals and a hundred or more System Controllers. The system operator may find it necessary to only audit certain suspected Sales Terminals and Controllers, rather than all such units. While some system operators may not use the audit capability immediately, the data collection function must be built into each terminal from the outset, as it is impractical to retrofit such a capability later. There should be sufficient circular buffer storage in Sales Terminals and System Controllers for at least one year, and preferably three years of transactions. Remote Terminals do not store transactions; they are stored in the associated System Controller. The Audit Recorder may access this stored data either directly, at the System Controller, or through any attached Remote Terminal.

5.2. Read from Sales Terminal by Audit Recorder

5.2.1. Log of all previous transactions, back to and including the last audit read. Transactions logged include:

5.2.1.1. Reads of RFID tags, including previous transactions

5.2.1.2. Sales

5.2.1.3. Audit reads

5.2.1.4. Maintenance work on Sales Terminal including:

5.2.1.4.1. Date/time of maintenance

5.2.1.4.2. Entry into system enclosures

5.2.1.4.3. Worker ID number from his/her RFID tag

5.2.2. If desired, the Audit Recorder can recover, in addition to the data since the last audit read, all previous transactions remaining in the Sales Terminal's log file. This circular buffer is large enough to allow retrieval of the data accumulated and read out over the course of several previous audit read cycles, thus allowing the recovery of misplaced or stolen data. No change may be made to the data stored in the log file of each Sales Terminal.

5.3. Written To Sales Terminal By Audit Recorder

5.3.1. Update of Sales Terminal's date/time clock.

5.3.2. Date and time of read

5.3.3. Serial number of Audit Recorder (cannot be changed in the field)

5.3.4. Audit operator's ID number

5.3.4.1. Read from his/her RFID tag

5.3.4.2. ID number cannot be changed in the field.

5.3.5. Updated list of invalid sales clerk ID numbers

5.3.6. Updated list of invalid System Controller serial numbers

5.4. Read From System Controller By Audit Recorder

5.4.1. Log of all previous transactions, back to and including the last audit read. Transactions logged include:

5.4.1.1. Debits

5.4.1.2. Audit reads

5.4.1.3. Maintenance work on System Controller including:

5.4.1.3.1. Date/time of maintenance

5.4.1.3.2. Entry into system enclosures

5.4.1.3.3. Worker ID number from his/her RFID tag

5.4.2. If desired, the Audit Recorder can recover, in addition to the data since the last audit read, all previous transactions remaining in the System Controller's log file. This circular buffer is large enough to allow retrieval of the data accumulated and read out over the course of several previous audit read cycles, thus allowing the recovery of misplaced or stolen data. No change may be made to the data stored in the log file of each System Controller.

5.5. Written To System Controller By Audit Recorder

5.5.1. Update of System Controller's date/time clock.

5.5.2. Date and time of read

5.5.3. Serial number of Audit Recorder (cannot be changed in the field)

5.5.4. Audit operator's ID number

5.5.4.1. Read from his/her RFID tag

5.5.4.2. ID number cannot be changed in the field.

5.5.5. Updated list of invalid sales clerk ID numbers

5.5.6. Updated list of invalid Sales Terminal serial numbers

6. Environmental Specifications

6.1. Operating (All System Components Except System Controller and Meter/Contactor)

6.1.1. Temperature: −20° C. to +50° C.

6.1.2. Humidity: 0 to 95%

6.2. Operating (System Controller and Meter/Contactor)

6.2.1. Temperature: −30° C. to +70° C.

6.2.2. Humidity: 0 to 95%

6.3. Storage (All System Components)

6.3.1. Temperature: −40° C. to +85° C.

6.3.2. Humidity: 0 to 100%

What is claimed is:

1. A utility payment system comprising:
a remote communication unit including a utility meter having a payment acceptor integral with or proximate said meter;
a customer interface unit for conducting a transaction;
radio frequency identification (RFID) communication means for communicating between the payment acceptor and the customer interface; and
a control system adapted to effect payment for a utility transaction through value received through said payment acceptor via said wireless communication electronics.

2. The system of claim 1 wherein said customer interface unit includes:
available value storage means for storing data representing a prepaid amount;
means for selectively incrementing said prepaid amount in response to customer payment; and
means for decrementing said prepaid amount by said value received in response to said payment for a utility transaction.

3. The system of claim 1 wherein said utility meter is an electric power consumption meter, said system further comprising means for enabling delivery of electrical current through said power meter in response to said transaction.

4. A method for conducting a utility transaction at or near a utility meter with a remote communication unit, said meter having a payment acceptor integral with or proximate said dispenser, comprising the steps of:
a. adding a value received through said payment acceptor to a prepaid value stored in association with said remote communication unit to increase the prepaid value stored in association with the remote communication unit;
b. using RFID, reading the prepaid value stored in association with the remote communication unit;
c. totaling a purchase cost for a utility consumption subject to the transaction;
d. deducting the purchase cost from the prepaid value to calculate an updated prepaid value; and
e. using RFID, storing the updated prepaid value in association with the remote communication unit.

5. The method of claim 4 wherein:
the storing step in (e) further comprises reading said prepaid value from a database apart from the remote communication unit and writing the updated prepaid value to said database apart from said remote communication unit;
a customer prepays for subsequent transactions at a terminal capable of communicating by RFID with said remote communication unit to store said prepaid value on said remote communication unit.
